(19) United States
(12) Patent Application Publication
(10) Pub. No.: US 2022/0373624 A1
(43) Pub. Date: Nov. 24, 2022

(54) Permittivity Enhanced Magnetic Resonance Imaging (MRI) And Magnetic Resonance Spectroscopy (MRS)

(71) Applicants: Zepp, Inc., Cupertino, CA (US); Anhui Huami Health Technology Co., Ltd., Hefei (CN)

(72) Inventors: Jinghua Wang, Cupertino, CA (US); Kongqiao Wang, Hefei (CN); Liyun Lu, Hefei (CN)

(21) Appl. No.: 17/707,539

(22) Filed: Mar. 29, 2022

Related U.S. Application Data
(60) Provisional application No. 63/191,728, filed on May 21, 2021.

(51) Int. Cl. G01R 33/34; G01R 33/565; G01R 33/24

(52) U.S. Cl. CPC G01R 33/34046; G01R 33/5659; G01R 33/246

(57) ABSTRACT

A permittivity apparatus that includes a permittivity material is received. The permittivity material includes one or more types of high permittivity materials. The permittivity apparatus is configured to be placed near or into a region of interest to be imaged. The permittivity apparatus is placed near or into the region of interest such that placing the permittivity apparatus near or into the region of interest changes a local stored electromagnetic energy distribution around or inside the region of interest. MRI images including the region of interest are then acquired. An MRI system includes radiofrequency coils and a permittivity apparatus that includes one or more types of high permittivity materials. The permittivity apparatus is configured to be placed near or into a region of interest to be imaged.

### CROSS-REFERENCE TO RELATED APPLICATION(S)

This disclosure claims the benefit and priority of U.S. Provisional Application No. 63/191,728, filed May 21, 2021, the disclosure of which is hereby incorporated by reference in its entirety.

### TECHNICAL FIELD

This disclosure relates generally to magnetic resonance and more specifically to high permittivity material for use in magnetic resonance.

### BACKGROUND

Many diseases and abnormal body conditions (such as tumors, strokes, heart problems, spine diseases, etc.) can be detected using magnetic resonance imaging (MRI). MRI creates images that can show differences between healthy and unhealthy tissue. MRIs can be a safer imaging technology than, for example, x-ray or computed tomography (CT) at least because patients and medical personnel are not subjected to ionizing radiation exposure during the imaging procedure. To obtain an image of a region of interest (ROI), a powerful, constant magnetic field, rapidly changing local magnetic fields, radiofrequency (RF) energy, and dedicated equipment are used.

RF coils can be used to produce an RF magnetic field. The RF magnetic field is referred to as a B₁ field. The B₁ field can be used to excite and detect a magnetization signal of the ROI. The RF field can be transmitted into the ROI to excite nuclear spins. Subsequently, the RF signals from the nuclear spins decay and induce a current in RF receiver coils (which may be the same or different from the RF transmitter coils).

A high-quality scan (i.e., image) is important for maximizing diagnostic sensitivity and accuracy. High quality images can be characterized by high signal to noise ratio (SNR), high contrast between normal and pathological tissues, low levels of artifacts, appropriate spatial-temporal resolution, or a combination thereof. Generally, the spatial resolution and the temporal resolution are inversely related. Temporal resolution refers to the duration of image capture of a ROI. Spatial resolution refers to the size (e.g., dimensions, etc.) of the ROI.

### SUMMARY

Aspects disclosed herein use high permittivity materials with low electrical conductivity or without conductivity for changing an RF field distribution of the radiofrequency (RF) electromagnetic field of magnetic resonance imaging (MRI) and magnetic resonance spectroscopy (MRS) spectroscopy instruments, and then enhancing the quality of MRI and MRS. An MRI and an MRS system may be referred to herein, collectively, as an MRI system.

A first aspect of the disclosed implementations is a method of using a permittivity apparatus for imaging in an MRI system. The method includes receiving the permittivity apparatus, where the permittivity apparatus comprises a permittivity material and is configured to be placed near or into a region of interest to be imaged; placing the permittivity apparatus near or into the region of interest such that placing the permittivity apparatus near or into the region of interest changes a local stored electromagnetic energy distribution around the region of interest; and acquiring MRI images including the region of interest. The permittivity material results in an increase in image quality of the acquired MRI images. The permittivity material can include one or more types of high permittivity materials.

A second aspect is an MRI system that includes one or more radiofrequency coils and a permittivity apparatus that includes a permittivity material, which can include one or more types of high permittivity materials. The permittivity apparatus is configured to be placed near or into a region of interest to be imaged between the one or more radiofrequency coil and the region of interest. The high permittivity material is configured to cause an increase in stored electromagnetic energy of the region of interest and cause an increase in a regional Q factor of the region of interest.

A third aspect is an MRI system that includes one or more radiofrequency coils and a permittivity apparatus that includes a permittivity material, which can include one or more types of high permittivity materials. The permittivity apparatus is configured to be implanted in a region of interest to be imaged. The high permittivity material is further configured to cause an increase in stored electromagnetic energy of the region of interest and cause an increase in a regional Q factor of the region of interest.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a side view of an example of an MRI system without a permittivity apparatus.

FIG. 2 is a block diagram of an example of a computing device.

FIG. 3 is a flowchart of an example of a technique for using a high permittivity material to image a region of interest (ROI).

FIG. 4 is a side view of an example of an MRI system with a permittivity apparatus.

### DETAILED DESCRIPTION

A high-quality MRI scan is important for maximizing diagnostic sensitivity and accuracy. Generally, and as mentioned above, high quality images are characterized by high signal to noise ratio (SNR), high contrast between normal and pathological tissues, low levels of artifacts, and appropriate spatial-temporal resolution.

In order to obtain a detectable MR signal, an object or a subject (collectively, an object) to be examined is positioned in a homogeneous static magnetic field so that the nuclear spins of the object generate a net magnetization that is oriented along the static magnetic field. The net magnetization can be rotated away from the static magnetic field using a radio frequency (RF) excitation field with the same frequency as the Larmor frequency of the nucleus.

The angle of the rotation can be determined by the field strength and/or duration of the RF excitation pulse. At the end of the RF excitation pulse, the nuclei, in relaxing to their normal spin conditions, generate a decaying signal (the “MR signal”) at the same radio frequency as the RF excitation. The MR signal can be picked up (e.g., collected, detected, etc.) by a receive coil. The MR signal can be amplified and processed (such as by a computing device) to obtain MR images. The acquired measurements, which may be collected in the spatial frequency domain, can be digitized and stored as complex numerical values in a k-space matrix. An associated MR image can be reconstructed from the k-space data, for example, by an inverse 2D or 3D fast Fourier transformation (FFT) from the raw k-space data.

However, various conventional approaches and techniques are less than ideal for obtaining high quality images characterized by high signal to noise ratio (SNR), high contrast between normal and pathological tissues, low levels of artifacts, and appropriate spatial-temporal resolution as there are limits to maximizing the effect of a dielectric material with high-permittivity on at least one of the transmission or reception in an MRI system. Most conventional approaches and techniques focus on improving radio frequency homogeneity or specific absorption rates. Additionally, various conventional approaches and techniques have focused on the impact of the materials on the magnitude and phase of radiofrequency fields by placing high permittivity materials or permeability materials between a radiofrequency coil and a region of interest being imaged to modify the magnitude and the phase of radiofrequency fields at high field MRI or ultra-high field to improve MRI image quality and MRI safety. Furthermore, the conventional approaches fail to teach putting the high permittivity materials or permeability materials into the region of interest. For example, the high permittivity materials or permeability materials may be placed into the mouth of a patient to improve the quality of brain MRI imaging.

Apparatuses, materials, and techniques described herein can improve the quality of acquired MRI images. High permittivity material with low lossy or without lossy can be placed near (e.g., around, proximal, in touch with, or inserted into) a region of interest. For example, as mentioned above, the high permittivity materials or permeability materials may be placed into the mouth of a patient. The high permittivity material is such that it causes an increase in the stored electromagnetic energy and increase in the regional Q factor of the region of interest. The increased Q factor can transfer into (e.g., results in, etc.) improvements in image quality. The high-permittivity materials, as disclosed herein, can be used with any field strength MRI, such as high field MRI (≥1.5 Tesla), ultra-high field MRI (>=7.0 Tesla), or low-field MRI (e.g., 1-199 mT). In low-field MRI, it is important that reduced polarization of nuclear numbers leads to the very low signal-to-noise ratios and contrast-to-noise ratios. As such, in an implementation, the high permittivity material can be used in an MRI system with a static magnetic field that is in the range from 0.5 Gauss to 15 Tesla. Some MRI system use the earth's magnet (i.e., 0.5 Gauss); whereas others can use up to 15 Tesla, which is typically used for humans.

Using the high-permittivity materials, as disclosed herein, can improve the local or regional stored electromagnetic energy density around a targeted ROI being imaged. The effect of a dielectric material with high permittivity on the local or regional stored electromagnetic energy density around the targeted region of interest being imaged is further described. Using the high-permittivity materials with low electrical conductivity, as described herein, can change the RF field distribution of the radiofrequency (RF) electromagnetic field of magnetic resonance imaging (MRI) and magnetic resonance spectroscopy (MRS) spectroscopy instruments therewith enhancing the quality of MRI and MRS MRI. Using the high-permittivity material with low electrical conductivity, as described herein, can result in improved signal-to-noise ratio (SNR) and contrast-to-noise ratio (CNR) of a region of interest to be imaged.

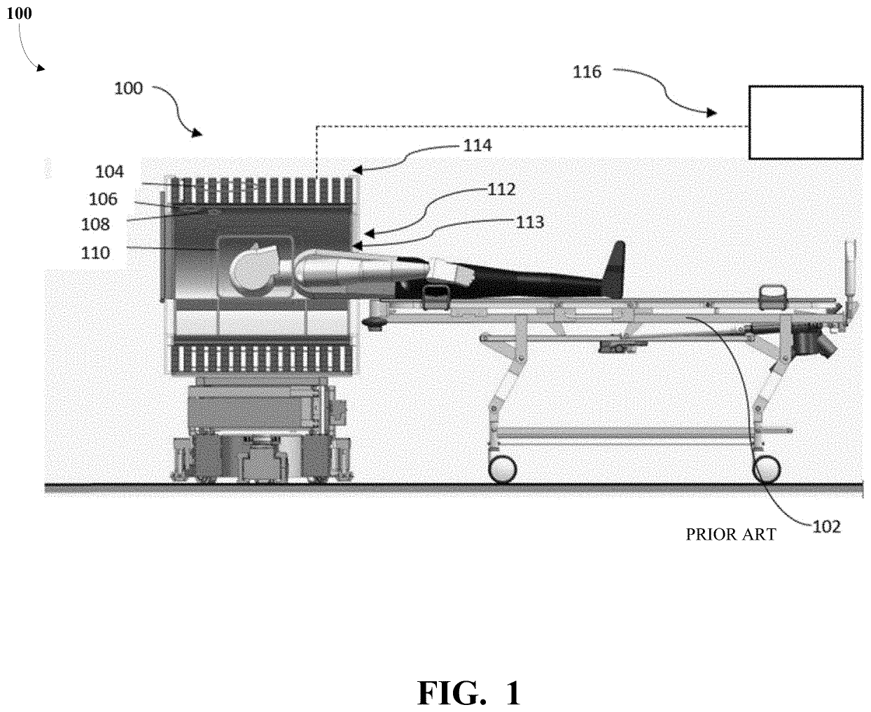

FIG. 1 is a side view of an example of an MRI system 100 without a permittivity apparatus. The MRI system 100 may be movable and usable with any patient table 102 or bed. The patient table 102 may be raised or lowered to a height of the MRI system 100 or the MRI system 100 may be raised or lowered to a height of the patient table 102. The MRI system 100 includes a permanent magnet 104. The permanent magnet 104 surrounds the patient while the patient is located in a magnet bore 113 of the permanent magnet 104. The permanent magnet 104 may work in conjunction with gradient coils 106.

The gradient coils 106 may assist the permanent magnet 104 in creating an electric field. The electric field (e.g., a strong static magnetic field) may be created in any direction of an x, y, z, coordinate system. The MRI system 100 includes one or more radio transmission coils, RF TX coils 108, that transmits electric fields, which move the magnetic fields created by the permanent magnet 104. One or more radio transmission reception coils, RF RX coils 110, receives and measures the electric field moved by the RF TX coils 108. The electric fields measured by the RF TX coils 108 and RF RX coils 110 pass through a patient located within an interior 112 of the MRI system 100, which as shown in FIG. 1 is the magnet bore 113 within the permanent magnet 104. The RF TX coil 108, the RF RX coils 110, or both may operate within a radio frequency of about 200 MHz or less, about 100 MHz or less, about 50 MHz or less, or about 25 MHz or less. The RF TX coil 108, the RF RX coils 110, or both may operate within a radio frequency of about 1 KHz or more, about 50 KHz or more, about 100 KHz or more, about 1 MHz or more, or about 10 MHz or more. Preferably, the RF TX coil 108, the RF RX coils 110, or both may operate within a radio frequency of about 1 MHz to about 10 MHz.

The magnet bore 113 of the MRI system 100 may be sufficiently large to fit all or a portion of a human. The magnet bore 113 may fit a torso of any individual. The magnet bore 113 may have a length that is about 1 m or more, about 1.25 m or more, about 1.5 m or more, or about 1.75 m or more. The magnet bore 113 may have a length that is about 2.5 m or less, about 2.25 m or less, or about 2 m or less. The magnet bore 113 may have cross-sectional length (e.g., diameter) of about 0.5 m or more, about 0.75 m or more, or about 1 m or more. The magnet bore 113 may have a cross-sectional length of about 2 m or less, about 1.5 m or less, or about 1.25 m or less. The cross-section of the MRI system 100 may be symmetrical, asymmetrical, circular, oval, geometric, nongeometric, or a combination thereof. The magnet bore 113 of the portable system may be spaced apart from the exterior 114 by walls of the MRI system 100. The magnet bore 113 may be an interior of the portable system. The magnet bore 113 may receive all or a portion of a patient. The magnet bore 113 may include a shutter that is openable or closeable. The shutter may be a plate that is moved over the removable shielding 122. A computing device 116 is connected to the MRI system 100 to control the portable system and provide feedback to a user.

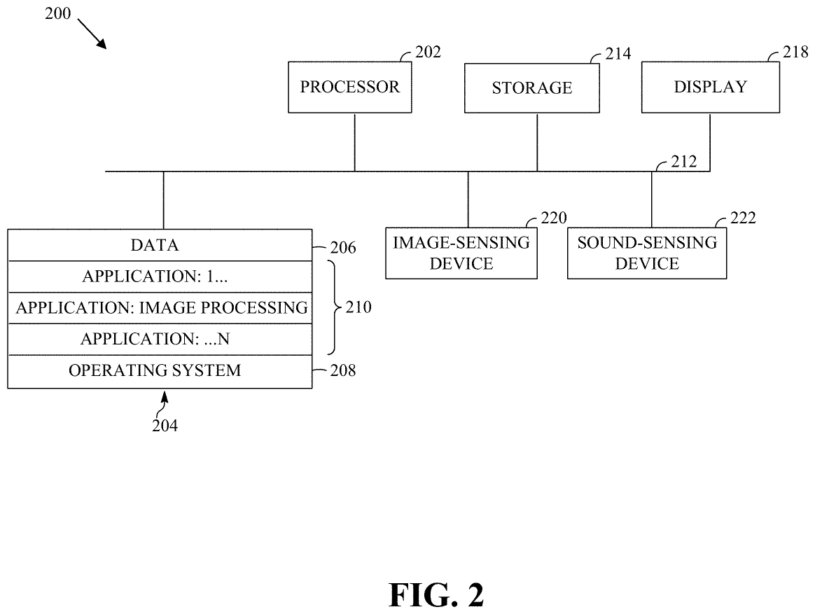

FIG. 2 is a block diagram of an example of a computing device 200. The computing device 200 can be in the form of a computing system including multiple computing devices, or in the form of a single computing device, for example, a mobile phone, a tablet computer, a laptop computer, a notebook computer, a desktop computer, and the like. The computing device can be communicatively connected to an MRI system, for example, to receive images from the MRI system or to control aspects of the MRI system.

A CPU 202 in the computing device 200 can be a central processing unit. Alternatively, the CPU 202 can be any other type of device, or multiple devices, capable of manipulating or processing information now existing or hereafter developed. Although the disclosed implementations can be practiced with a single processor as shown, e.g., the CPU 202, advantages in speed and efficiency can be achieved using more than one processor.

A memory 204 in the computing device 200 can be a read-only memory (ROM) device or a random-access memory (RAM) device in an implementation. Any other suitable type of storage device can be used as the memory 204. The memory 204 can include code and data 206 that is accessed by the CPU 202 using a bus 212. The memory 204 can further include an operating system 208 and application programs 210, the application programs 210 including at least one program that permits the CPU 202 to perform the methods described here. For example, the application programs 210 can include applications 1 through N, which further include an image processing application that can be used enhance, view, process, or the like, images obtained from an MRI system or an application for controlling aspects of the MRI system. The applications can include an application that can be used to configure or control the MRI system. The computing device 200 can also include a secondary storage 214, which can, for example, be a memory card used with a computing device 200 that is mobile.

The computing device 200 can also include one or more output devices, such as a display 218. The display 218 can be, in one example, a touch sensitive display that combines a display with a touch sensitive element that is operable to sense touch inputs. The display 218 can be coupled to the CPU 202 via the bus 212. Other output devices that permit a user to program or otherwise use the computing device 200 can be provided in addition to or as an alternative to the display 218. When the output device is or includes a display, the display can be implemented in various ways, including by a liquid crystal display (LCD), a cathode-ray tube (CRT) display or light emitting diode (LED) display, such as an organic LED (OLED) display.

The computing device 200 can also include or be in communication with an image-sensing device 220, for example a camera, or any other image-sensing device 220 now existing or hereafter developed that can sense an image such as the image of a user operating the computing device 200. The image-sensing device 220 can be positioned such that it is directed toward the user operating the computing device 200. In an example, the position and optical axis of the image-sensing device 220 can be configured such that the field of vision includes an area that is directly adjacent to the display 218 and from which the display 218 is visible.

The computing device 200 can also include or be in communication with a sound-sensing device 222, for example a microphone, or any other sound-sensing device now existing or hereafter developed that can sense sounds near the computing device 200. The sound-sensing device 222 can be positioned such that it is directed toward the user operating the computing device 200 and can be configured to receive sounds, for example, speech or other utterances, made by the user while the user operates the computing device 200.

Although FIG. 2 depicts the CPU 202 and the memory 204 of the computing device 200 as being integrated into a single unit, other configurations can be utilized. The operations of the CPU 202 can be distributed across multiple machines (each machine having one or more of processors) that can be coupled directly or across a local area or other network. The memory 204 can be distributed across multiple machines such as a network-based memory or memory in multiple machines performing the operations of the computing device 200. Although depicted here as a single bus, the bus 212 of the computing device 200 can be composed of multiple buses. Further, the secondary storage 214 can be directly coupled to the other components of the computing device 200 or can be accessed via a network and can comprise a single integrated unit such as a memory card or multiple units such as multiple memory cards. The computing device 200 can thus be implemented in a wide variety of configurations.

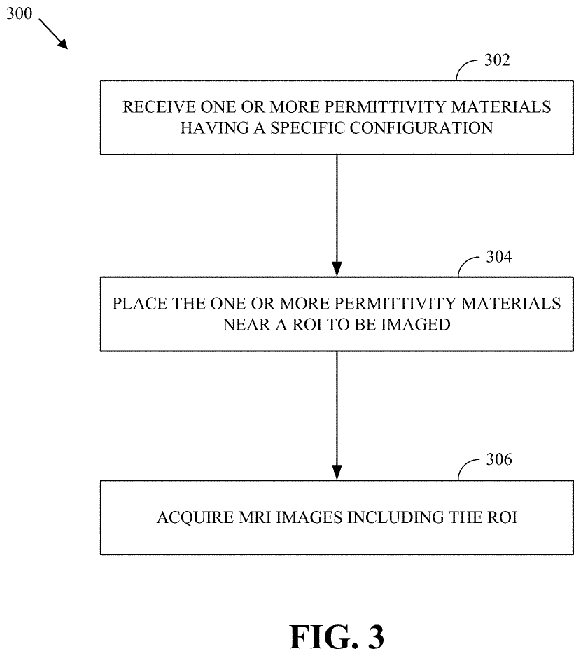

FIG. 3 is a flowchart of an example of a technique 300 for using a high permittivity material to image a region of interest (ROI). The permittivity material can be, or can be included in an apparatus, referred to herein as a high permittivity apparatus. The permittivity material can be one or more permittivity materials or one or more apparatuses. That is, the permittivity apparatus can be configured by or include one or more types of high permittivity materials. Stated yet another way, the permittivity material can be or include one or more types of high permittivity materials. The ROI is to be imaged using a particular MRI system.

At 302, one or more permittivity materials having a specific configuration can be received (e.g., obtained, used, etc.). The configuration can be such that the stored energy can be maximized in or around the ROI.

By high permittivity material is meant that the permittivity of the material used is higher than the permittivity of the ROI being imaged. In an example, the relative permittivity can be higher than 70. As is known, the permittivity of brain tissue is close to 70 and that of water is 80. The permittivity material can be or have low lossy or can be without lossy. The high permittivity material can be placed near the ROI. As mentioned above, placing the permittivity material near the ROI includes placing the permittivity material (or, equivalently, at least a portion of a permittivity apparatus that includes the permittivity material) around, proximal to, in touch with, or inserted into the ROI. The closer the high permittivity material is placed to the region of interest, the better the improvement in image quality. Placing the permittivity material near the ROI can encompasses placing the high permittivity material around (e.g., on, surrounding, etc.), proximal, or implanted in the ROI. The permittivity materials may be implanted in human organs for MRI based brain-computer interface. Different material can be used. As such, the relative permittivity of the permittivity apparatus can be in the range of 1 to 3000.

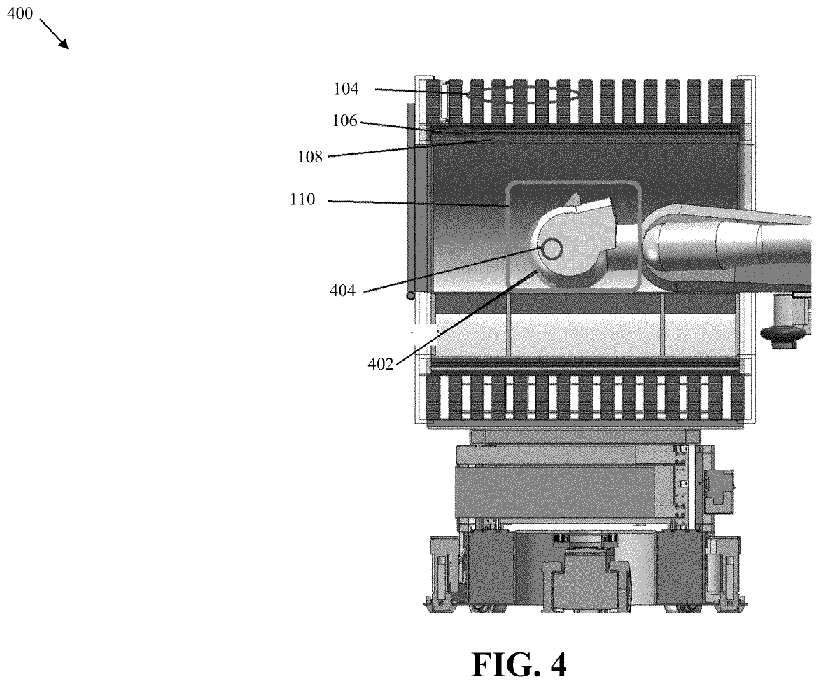

FIG. 4 is a side view of an example of an MRI system 400 with a permittivity apparatus. FIG. 4 illustrates placing a permittivity apparatus 402 near a region of interest 404. The permittivity apparatus 402 can be on include high permittivity material. Like numerals between FIG. 4 and FIG. 1 generally designate like or corresponding elements and descriptions therefore are omitted with respect to FIG. 4.

The configuration (e.g., shape, composition, etc.) of high permittivity materials can be optimized separately for transmission and reception. The permittivity apparatus 402 (e.g., the high permittivity apparatus) can have a configuration that is based on the imaging area, the scanning device (e.g., the MRI system) used, the material type of the permittivity apparatus 402, more criteria, fewer criteria, other criteria, or a combination thereof. The configuration can be selected so as reach the best Q factor or the best signal to noise ratio and image quality. In an example, the configuration of the permittivity apparatus 402 can include the geometric properties of the high permittivity apparatus.

For a transceiver coil, the different polarizations of transmit field and receiver field respectively contribute to the MRI signal. Thus, the optimal structures of high permittivity materials can be configured differently for transmission and receptions. If a permittivity apparatus is used for both a transmission and a reception, a trade-off can be made as to the effect of the permittivity apparatus on both the transmission and the reception. Certain materials or configurations may be better suited for optimizing the receive field while other materials or configurations may be better suited for optimizing the transmit field. However, due to timing issues during imaging, only one material may be used for both transmission and receiving. As such, the material or configuration can be chosen so as to optimize for better transmission or better receiving.

At 304, the permittivity apparatus 402 can be placed near the ROI. Placing the permittivity apparatus 402 near the ROI increases the stored electromagnetic energy in the ROI. Increasing the stored electromagnetic energy in the ROI in turn increases the regional Q factor of the ROI. The increased Q factor can transfer into (e.g., result in, etc.) improvements in image quality.

By placing the permittivity apparatus 402 near to the imaging area (i.e., the ROI), more electromagnetic energy can be stored near the region of interest 404. The amount of lost energy can be determined by the conductivity or lossy of the material. As a result, a better Q factor can be obtained near the region of interest 404 and a better SNR of the region of interest 404 can be achieved. Additionally, the lower the conductivity of the permittivity material, the lower the energy loss. As such, by using permittivity material with lower conductivity, the energy loss can be lowered according to the Q value. If the Q value is higher, the image quality can be better. As is known, the Q value is defined as Q=(stored energy)/(lost energy). As such, in an implementation, the material can have high permittivity with low conductivity or lossy.

It is noted that the permittivity apparatus 402 described herein is not necessarily intended to modify the magnitude or phase of radiofrequency fields. Rather, the target (e.g., focus) of the permittivity apparatus 402 disclosed herein is energy. That is, energy can be focused in the permittivity apparatus 402. However, in an implementation, the permittivity apparatus 402 can be configured so as to increase homogeneity of the transmit field to a desired homogeneity.

In an implementation, the permittivity apparatus 402 can be configured so as to reduce the relative lossy. The lossy can be reduced based on the configuration, the conductivity of the material (such as the type of material of the permittivity apparatus 402), or both. The permittivity apparatus 402 can cause an increase of the radiofrequency electromagnetic energy stored within the region of interest 404 during reception. The permittivity apparatus 402 can cause an increase of receive sensitivity to the region of interest 404 during reception.

At 306, the technique 300 acquires MRI images including the ROI. The technique 300 improves the image quality of the acquired MRI images by placing the permittivity apparatus near the region of interest 404. By placing the permittivity apparatus near the region of interest 404, the quality of acquired images is improved as compared to images that would have been obtained without using the permittivity material as described herein.

In an example, the permittivity material can have a high permittivity with a low conductivity or lossy. In an example, the main magnetic field of the MRI system 400 can be more than or equal to 1.5 Tesla. In an example, the main magnetic field of the MRI system 400 can be less than 1.5 Tesla. In an example, the main magnetic field of the MRI system 400 can be less than 0.1 Tesla. In an example, the main magnetic field of the MRI system 400 can be less than 0.01 Tesla. In an example, the permittivity apparatus 402 can be configured to increase a store of electromagnetic energy within the region of interest 404 during a radiofrequency coil transmission. In an example, the permittivity apparatus 402 can be configured to increase a positive circularly polarized field within the region of interest 404 during a radiofrequency coil transmission.

In an example, the permittivity apparatus 402 (more specifically, the permittivity material of the permittivity apparatus 402) can be configured to increase a store of electromagnetic energy within the region of interest 404 during a radiofrequency coil reception. In an example, the permittivity material can be configured to increase a negative circularly polarized field within the region of interest 404 during a radiofrequency coil reception. In an example, the relative permittivity of the permittivity material can be more than 60. In an example, the relative permittivity of the permittivity material can be more than 100. In an example, the relative permittivity of the permittivity material can be more than 500. In an example, the relative permittivity of the permittivity material can be more than 1000.

The region of interest 404 can be or include a whole or part of an organ. The region of interest 404 can be or include one or more lesions. In an example, the permittivity apparatus can be configured to accomplish at least one of increasing a stored radiofrequency electromagnetic energy within the region of interest during transmission; increasing a homogeneity of a transmit field; reducing a relative lossy of a radiofrequency electromagnetic energy during transmission; increasing a stored radiofrequency electromagnetic energy within the region of interest during reception; or increasing a receive sensitivity to the region of interest during reception. In an example, the permittivity apparatus can be configured to have a first configuration for radiofrequency transmission and a second configuration for radiofrequency reception where the first configuration is different from the second configuration.

In an example, the permittivity apparatus 402 can be configured to optimize a transmit radiofrequency field homogeneity or transmit efficiency for radiofrequency transmission. In an example, the permittivity apparatus 402 can be configured to ensure receive efficiency and receive sensitivity for radiofrequency reception. In an example, the permittivity apparatus 402 can be implanted into a body around the region of interest.

### DEFINITIONS

As used herein, volume coils (e.g., body coil) refer to coils of an MRI system that completely encompass the region of interest being imaged and can be operated as transmit coils, or receiver coils, or both.

As used herein, B₁⁺ refers to the positive circularly polarized component of a transversal transmit field of a radiofrequency (RF) pulse, which is generated by a transmit coil. The RF pulse can be used as an excitation RF pulse, refocused RF pulse, and magnetization preparation RF pulse. The transmit coil can be at least one of volume coil, surface coil, one element of an array coils, or a combination thereof. The transversal transmit RF field can be decomposed into two rotating fields: the positive circularly polarized component B₁⁺, which rotates in the direction of nuclear magnetic moment precession (counterclockwise direction), and the negative circularly polarized component B₁⁻, which rotates opposite to the direction of precession (clockwise direction). In an MRI system, only the positive circularly polarized component of the transmitting field B₁⁺ contributes to the excitation of proton nuclei spins. Therefore, as used herein, B₁⁺ refers to the transmit field of a transmit coil.

An MRI system according to this disclosure herein can include a plurality of transmit coils and/or a plurality of receiver coils. Optionally, the transmit and/or receiver coils can be an array coil (e.g., transmit coil elements arranged in an array and/or receiver coil elements arranged in an array). In some implementations, the transmit and receiver coils can be different coils. In other implementations, the transmit and receiver coil can be the same coil (e.g., a transceiver coil). Alternatively or additionally, the transmit coil can include, but is not limited to, a transmit volume coil, a transmit surface coil, or an array coil. In some implementations, the most important characterizations of RF fields during MRI transmission include transmit efficiency, B₁⁺ homogeneity and specific absorption rate (SAR) in the subject being imaged. The B₁⁺ inhomogeneity is important for quantitative MRI, such as quantitative fast T1 mapping and MR image segmentation. It is known that contrast-to-noise ratio and signal inhomogeneity are major factors that strongly affect the performance of segmentation.

Inhomogeneous transmit or inhomogeneous receiver sensitivity (or both) can give rise to signal and contrast inhomogeneities in the reconstructed images. Without removing or sufficiently reducing these electromagnetic field inhomogeneities over the subject being imaged, the value of MRI images in clinic and research may be compromised.

Specific absorption rate (SAR) can be very important for RF safety in an MRI system, particularly in high field and ultra-high field MRI. The transmit field inhomogeneities can generate a local exposure where most of the absorbed energy is applied to one body region rather than the entire body. As a result, hotspots may occur in the exposed tissues and may lead to regional damage of these exposed tissues even when the global SAR is less than U.S. Food and Drug Administration (FDA) and International Electrotechnical Commission (IEC) SAR limits.

As used herein, transmit efficiency of a transmit coil in MRI system refers to the ratio of B₁⁺ generated by the transmit coil to the power supplied to the transmit coil, that is, the B₁⁺ magnitude per power.

As mentioned above, B₁⁻ refers to the negative circularly polarized component of a transversal receiver field of a receiver coil that is generated by a receiver coil in MRI system. The transversal receiver field may be decomposed into two rotating fields: the positive circularly polarized component B₁⁺ which rotates in the direction of nuclear magnetic moment precession (counterclockwise direction), and the negative circularly polarized component B₁⁻, which rotates opposite to the direction of precession (clockwise direction). In an MRI system, the receiver sensitivity in MRI system is proportional to the negative circularly polarized component of the receiver field B₁⁻.

As used herein, a permittivity material refers to a material that can store electrical potential energy under the presence of an electric field. Relative permittivity is defined as the permittivity of a given material relative to that of the permittivity of a vacuum. The permittivity of vacuum is equal to approximately 8.85×10⁻¹² Farads/meter. For example, the relative permittivity of human brain tissue is about 60; the relative permittivity of Teflon is about 2.1; the relative permittivity of Titanium dioxide is from 86 to 173; the relative permittivity of Lead zirconate titanate is from 500 to 600; and the relative permittivity of Conjugated polymers is from 1.8 up to 100,000.

As used herein, the term “permittivity loss” refers to lost energy. Energy can be lost because the permittivity material changes polarization, induces a tiny alternating current flow, and leads to the energy loss. Different materials have different losses at different frequencies.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. A method of using a permittivity apparatus for imaging in an MRI system, comprising:
receiving the permittivity apparatus, wherein the permittivity apparatus comprises a permittivity material and is configured to be placed near or into a region of interest to be imaged;
placing the permittivity apparatus or into near the region of interest, wherein placing the permittivity apparatus near or into the region of interest changes a local stored electromagnetic energy distribution around or inside the region of interest; and
acquiring MRI images including the region of interest, wherein the permittivity material results in an increase in image quality of the acquired MRI images.

2. The method of claim 1, wherein the permittivity apparatus is configured to accomplish at least one of:
increasing a stored radiofrequency electromagnetic energy within the region of interest during transmission;
increasing a homogeneity of a transmit field;
reducing a relative lossy of a radiofrequency electromagnetic energy during transmission;
increasing a stored radiofrequency electromagnetic energy within the region of interest during reception; or
increasing a receive sensitivity to the region of interest during reception.

3. The method of claim 1, wherein the permittivity material has a high permittivity with a low conductivity or lossy, and the permittivity material comprises one or more types of high permittivity materials.

4. The method of claim 1, wherein a main magnetic field of the MRI system is more than or equal to 1.5 Tesla.

5. The method of claim 1, wherein a main magnetic field of the MRI system is less than 1.5 Tesla.

6. The method of claim 1, wherein a main magnetic field of the MRI system is less than 0.1 Tesla.

7. The method of claim 1, wherein a main magnetic field of the MRI system is less than 0.01 Tesla.

8. The method of claim 1, wherein the permittivity material is configured to increase a store of electromagnetic energy within the region of interest during a radiofrequency coil transmission.

9. The method of claim 1, wherein the permittivity material is configured to increase a positive circularly polarized field within the region of interest during a radiofrequency coil transmission.

10. The method of claim 1, wherein the permittivity material is configured to increase a store of electromagnetic energy within the region of interest during a radiofrequency coil reception.

11. The method of claim 1, wherein the permittivity material is configured to increase a negative circularly polarized field within the region of interest during a radiofrequency coil reception.

12. An MRI system, comprising:
one or more radiofrequency coils; and
a permittivity apparatus comprising a permittivity material, wherein the permittivity apparatus is configured to be placed near or into a region of interest to be imaged between the one or more radiofrequency coil and the region of interest, wherein the permittivity material comprises one or more types of high permittivity materials and is further configured to:
cause an increase in stored electromagnetic energy of the region of interest, and
cause an increase in a regional Q factor of the region of interest.

13. The MRI system of claim 12, wherein a relative permittivity of the permittivity material is more than 60.

14. The MRI system of claim 12, wherein a relative permittivity of the permittivity material is more than 100.

15. The MRI system of claim 12, wherein a relative permittivity of the permittivity material is more than 500.

16. The MRI system of claim 12, wherein a relative permittivity of the permittivity material is more than 1000.

17. The MRI system of claim 12, wherein the permittivity apparatus is configured to have a first configuration for radiofrequency transmission and a second configuration for radiofrequency reception, wherein the first configuration is different from the second configuration.

18. The MRI system of claim 12, wherein the permittivity apparatus is configured to optimize a transmit radiofrequency field homogeneity or transmit efficiency for radiofrequency transmission.

19. The MRI system of claim 12, wherein the permittivity apparatus is configured to ensure receive efficiency and receive sensitivity for radiofrequency reception.

20. An MRI system, comprising:
one or more radiofrequency coils; and
a permittivity apparatus comprising a permittivity material, wherein the permittivity apparatus is configured to be implanted in a region of interest to be imaged, wherein the permittivity material comprises one or more types of high permittivity materials and is further configured to:
cause an increase in stored electromagnetic energy of the region of interest, and
cause an increase in a regional Q factor of the region of interest.
